(19) United States
(12) Patent Application Publication
(10) Pub. No.: US 2023/0389226 A1
(43) Pub. Date: Nov. 30, 2023

(54) COLD PLATE

(71) Applicant: Nidec Corporation, Kyoto (JP)

(72) Inventors: Keisuke KAWATA, Kyoto (JP); Toshihiko TOKESHI, Kyoto (JP); Takehito TAMAOKA, Kyoto (JP)

(21) Appl. No.: 18/202,321

(22) Filed: May 26, 2023

(30) Foreign Application Priority Data
May 27, 2022 (JP) 2022-087049

(51) Int. Cl. H05K 7/20

(52) U.S. Cl. CPC H05K 7/20254

(57) ABSTRACT

A cold plate includes an opposing portion, a cover portion, and a heat exchange chamber. The opposing portion opposes a heat generating component on one side in a first direction. The cover portion is arranged on another side of the opposing portion in the first direction. The heat exchange chamber includes at least the opposing portion and the cover portion to conduct heat from the heat generating component to a refrigerant through the opposing portion. The opposing portion includes a first cooling surface and a second cooling surface. The first cooling surface is provided on the one side in the first direction. The second cooling surface is provided on the one side in the first direction. The second cooling surface is spaced away from the first cooling surface in the first direction.

### CROSS-REFERENCE TO RELATED APPLICATIONS

The present application claims priority under 35 U.S.C. § 119 to Japanese Patent Application No. 2022-087049, filed on May 27, 2022, the entire contents of which are hereby incorporated herein by reference.

### 1. FIELD OF THE INVENTION

The present disclosure relates to a cold plate.

### 2. BACKGROUND

In a conventional cooling device, a heat receiving member that receives heat from a heating element by a refrigerant includes a base member that is thermally connected to the heating element. The base member is provided with a predetermined region of an opposing plane thermally connected to the heating element. For example, in a case where a heat generating component has undulation on a surface opposing the opposing plane of the heat receiving member, in the conventional cooling device, the area of the predetermined region thermally connected to the heating element becomes small, and it is difficult to sufficiently cool the heating element.

### SUMMARY

A cold plate according to an example embodiment of the present disclosure includes an opposing portion, a cover portion, and a heat exchange chamber. The opposing portion opposes a heat generating component on one side in a first direction. The cover portion is located on another side of the opposing portion in the first direction. The heat exchange chamber includes at least the opposing portion and the cover portion to conduct heat from the heat generating component to a refrigerant through the opposing portion. The opposing portion includes a first cooling surface and a second cooling surface. The first cooling surface is provided on the one side in the first direction. The second cooling surface is provided on the one side in the first direction. The second cooling surface is spaced away from the first cooling surface in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a view showing an outline of a cooling system including a cold plate of an example embodiment of the present invention.

FIG. 2 is a view showing a portion of a cooling assembly of an example embodiment of the present invention.

FIG. 3 is a view showing a cold plate separated from a heat generating component of an example embodiment of the present invention.

FIG. 4 is a view showing the heat generating component and the cold plate of FIG. 3 from a different angle.

FIG. 5 is a view showing a cold plate of an example embodiment of the present invention in a state where the opposing portion and the cover portion are separated from each other.

FIG. 6 is a view showing the opposing portion and the cover portion of FIG. 5 from a different angle.

FIG. 7 is a view showing the heat exchange chamber seen through from the other side in the first direction.

FIG. 8 is a sectional view of the heat exchange chamber taken along the second direction.

FIG. 9 is a view schematically showing a sectional view shown in FIG. 8.

### DETAILED DESCRIPTION

Hereinafter, example embodiments of the present disclosure will be described hereinafter with reference to the drawings. In the drawings, the same or corresponding parts are denoted by the same reference numerals, and the description will not be repeated. The present description appropriately describes a first direction Z, a second direction X, and a third direction Y orthogonal to one another for easy understanding. One side in the first direction Z is referred to as one side Z1 in the first direction, and the other side in the first direction Z is referred to as the other side Z2 in the first direction. One side in the second direction X is referred to as one side X1 in the second direction, and the other side in the second direction X is referred to as other side X2 in the second direction. One side in the third direction Y is referred to as one side Y1 in the third direction, and the other side in the third direction Y is referred to as the other side Y2 in the third direction. However, the directions are defined merely for convenience of explanation, and the orientations of the exemplary cold plate of the present disclosure in use are not limited unless the horizontal direction and the vertical direction need to be defined in particular. In the present description, the “orthogonal direction” includes a substantially orthogonal direction.

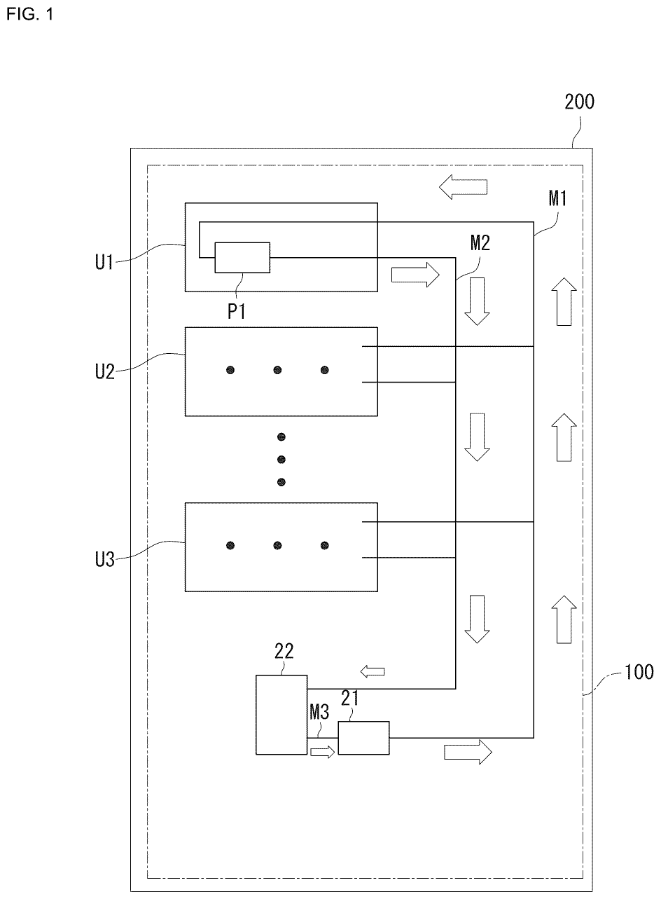

With reference to FIG. 1, a cooling system 100 including a cold plate P1 of the example embodiment will be described. FIG. 1 is a view showing an outline of the cooling system 100.

The cooling system 100 is provided in, for example, a computer device 200. The cooling system 100 cools the computer device 200. The computer device 200 is an example of electronic equipment. As an example, the cooling system 100 includes three cooling assemblies U1, U2, and U3, a manifold M1, a manifold M2, a pump unit 21, and a heat exchanger 22. The cooling system 100 may be provided to other than the computer device 200.

The pump unit 21 includes, for example, one or a plurality of pump devices. The plurality of pump devices are connected to each other in series or in parallel. Each of the pump devices has one or a plurality of pumps that sucks the refrigerant and discharges the refrigerant. The plurality of pumps are connected to each other in series or in parallel.

The pump unit 21 is connected to, for example, the manifold M1 and the manifold M2 through a flow path M3 and the heat exchanger 22. The manifold M1 is a pipe that connects, for example, the pump unit 21 and the cooling assemblies U1, U2, and U3. The flow path M3 is a pipe that connects, for example, the pump unit 21 and the heat exchanger 22. The refrigerant passes through inside the manifolds M1 and M2 and the flow path M3.

The pump unit 21 supplies the manifold M1 with the refrigerant. The refrigerant passes through inside the manifold M1. The manifold M1 distributes and supplies, to the cooling assemblies U1, U2, and U3, the refrigerant supplied from the pump unit 21. The refrigerants supplied to the cooling assemblies U1, U2, and U3 pass through the cooling assemblies U1, U2, and U3, respectively, and are supplied to the manifold M2. Hereinafter, the cooling assembly U1 will be representatively described. The configurations and functions of the cooling assemblies U2 and U3 are the same as those of the cooling assembly U1.

The cooling assembly U1 includes, for example, the cold plate P1. The cold plate P1 receives heat from a heat generating component (not shown) and cools the heat generating component. The heat generating component is, for example, an arithmetic device such as a CPU arranged in the computer device 200, a storage device such as a memory, and the like. The refrigerant passes through the cold plate P1 when passing through inside the cooling assembly U1. For example, the refrigerant performs heat exchange in the cold plate P1, whereby the refrigerant having heat circulates in the cooling system 100. The cooling assembly U1 may include two or more cold plates including the cold plate P1.

The manifold M2 is a pipe that connects, for example, the cooling assemblies U1, U2, and U3 and the heat exchanger 22. The refrigerant passes through inside the manifold M2. The manifold M2 joins and supplies, to the heat exchanger 22, the refrigerant that has passed through each of the cooling assemblies U1, U2, and U3. The refrigerant supplied to the heat exchanger 22 passes through the heat exchanger 22, for example. For example, the heat exchanger 22 is a radiator that radiates heat to the outside when a refrigerant having heat passes therethrough. The heat exchanger 22 includes, inside thereof, a plurality of refrigerant pipes through which the refrigerant passes inside thereof, and a plurality of fins arranged around the refrigerant pipes. A part of each of the plurality of fins is in contact with the refrigerant pipe. More specifically, the fin and the refrigerant pipe are joined by welding or the like. The fins absorb heat of the refrigerant pipe and the refrigerant and radiate the heat to the outside air, thereby lowering the temperature of the refrigerant. However, the heat exchanger 22 is not limited to a radiator that radiates heat to the outside. For example, the heat exchanger 22 may exchange heat with a flow path through which the refrigerant passes, which is other than the flow path through which the refrigerant passes.

The refrigerant having passed through the heat exchanger 22 passes through the flow path M3 and is supplied to the pump unit 21. The refrigerant supplied to the pump unit 21 is again supplied to the manifold M1 by the pump unit 21. As described above, in the cooling system 100, the refrigerant circulates through the pump unit 21, the manifold M1, the cooling assemblies U1, U2, and U3, the manifold M2, the heat exchanger 22, and the flow path M3. In FIG. 1, the circulation of the refrigerant is indicated by arrows. The refrigerant may circulate in opposite directions. The arrangement of the cooling assemblies U1, U2, and U3, the pump unit 21, and the heat exchanger 22 is merely an example, and other arrangements may be adopted.

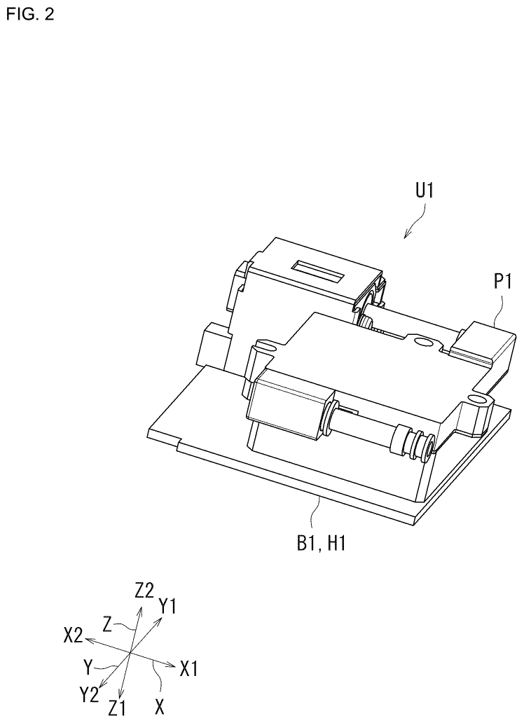

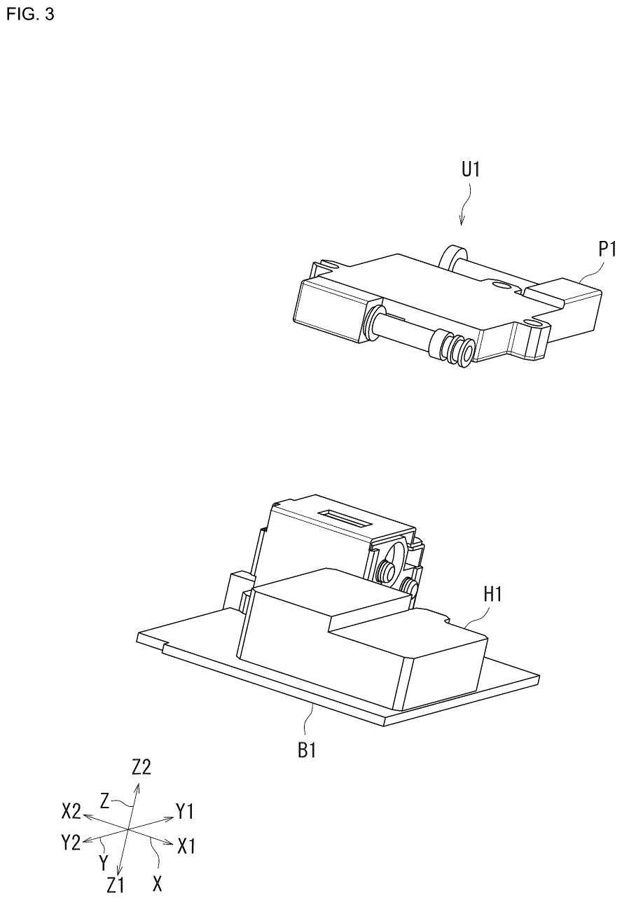

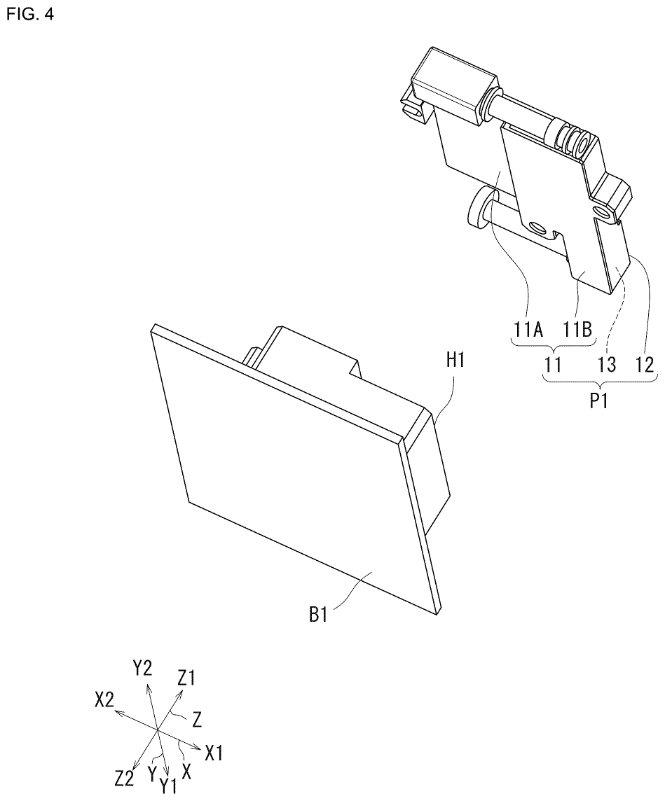

Next, the cold plate P1 will be described in detail with reference to FIGS. 2 to 4. FIG. 2 is a view showing a part of the cooling assembly U1. FIG. 3 is a view showing the cold plate P1 separated from a heat generating component H1. FIG. 4 is a view showing the heat generating component H1 and the cold plate P1 of FIG. 3 from a different angle.

For example, the cooling assembly U1 is arranged to oppose a board B1 arranged in the computer device 200. Specifically, the cold plate P1 of the cooling assembly U1 opposes the heat generating component H1 arranged on the board B1. In the present example embodiment, the heat generating component H1 extends along the first direction Z perpendicular to a mounting surface of the board B1. An end surface on the one side Z1 in the first direction of the heat generating component H1 is mounted on the board B1. An end surface on the other side Z2 in the first direction of the heat generating component H1 opposes the cold plate P1. That is, the cold plate P1 is positioned on the other side Z2 in the first direction of the heat generating component H1. In the present example embodiment, the end surface of the heat generating component H1 has undulation in the first direction Z.

The cold plate P1 includes an opposing portion 11, a cover portion 12, and a heat exchange chamber 13. The opposing portion 11 opposes the one side Z1 in the first direction with respect to the heat generating component H1. The cover portion 12 is arranged on the other side Z2 in the first direction of the opposing portion 11. The heat exchange chamber 13 includes at least the opposing portion 11 and the cover portion 12. The heat exchange chamber 13 conducts the heat of the heat generating component H1 to the refrigerant through the opposing portion 11. The opposing portion 11 has a first cooling surface 11A and a second cooling surface 11B. The first cooling surface 11A is provided on the one side Z1 in the first direction. The second cooling surface 11B is provided on the one side Z1 in the first direction. The second cooling surface 11B is positioned away in the first direction Z with respect to the first cooling surface 11A.

Therefore, since the first cooling surface 11A and the second cooling surface 11B oppose the end surface on the other side Z2 in the first direction of the heat generating component H1, for example, the area of the region where the first cooling surface 11A and the second cooling surface 11B come into contact with the end surface on the other side Z2 in the first direction of the heat generating component H1 becomes large. Therefore, the cold plate P1 can efficiently cool the heat generating component H1 including the plurality of surfaces having different positions in the first direction. As a result, the number of pipes connecting the plurality of cold plates to each other can be reduced as compared with the case where the cold plates are provided for the plurality of surfaces. Accordingly, the cooling surface of the cold plate can have a larger space, and the heat generating component H1 can be cooled more efficiently.

In the examples shown in FIGS. 2 to 4, the second cooling surface 11B is positioned away in the first direction Z with respect to the first cooling surface 11A. The second cooling surface 11B is positioned away on the one side Z1 in the first direction with respect to the first cooling surface 11A.

Specifically, the first cooling surface 11A and the second cooling surface 11B are provided stepwise in the first direction Z along the undulation of the end surface on the other side Z2 in the first direction of the heat generating component H1. That is, the first cooling surface 11A and the second cooling surface 11B have shapes along the end surface on the other side Z2 in the first direction of the heat generating component H1. For example, the first cooling surface 11A and the second cooling surface 11B are substantially parallel. For example, the shape of the first cooling surface 11A is substantially rectangular. The shape of the second cooling surface 11B is substantially rectangular. The first cooling surface 11A and the second cooling surface 11B are arranged side by side in the second direction X orthogonal to the first direction Z. Specifically, the second cooling surface 11B is positioned on the one side X1 in the second direction relative to the first cooling surface 11A. In other words, the first cooling surface 11A is positioned on the other side X2 in the second direction relative to the second cooling surface 11B. The shapes of the first cooling surface 11A and the second cooling surface 11B are not limited to be substantially rectangular. For example, the shapes of the first cooling surface 11A and the second cooling surface 11B are the same as the shape of the end surface on the other side Z2 in the first direction of the heat generating component H1.

For example, the first cooling surface 11A and the second cooling surface 11B are formed of a single member. This makes it easy to manufacture the opposing portion 11 as a single component, and makes it possible to reduce the number of members in the cold plate P1. In other words, the opposing portion 11 including the first cooling surface 11A and the second cooling surface 11B is formed as one component formed of a single member. As an example, the opposing portion 11 is made of metal having high thermal conductivity.

In the present example embodiment, the first cooling surface 11A and the second cooling surface 11B are arranged continuously in the second direction X, but the present disclosure is not limited to this, and the first cooling surface 11A and the second cooling surface 11B may be arranged apart from each other. The first cooling surface 11A and the second cooling surface 11B may be formed of different members. In the present example embodiment, as shown in FIGS. 2 and 3, the first cooling surface 11A and the second cooling surface 11B are in direct contact with the end surface on the other side Z2 in the first direction of the heat generating component H1, but the present disclosure is not limited to this, and the first cooling surface 11A and the second cooling surface 11B may oppose the end surface on the other side Z2 in the first direction of the heat generating component H1 through, for example, a heat conductive sheet or the like.

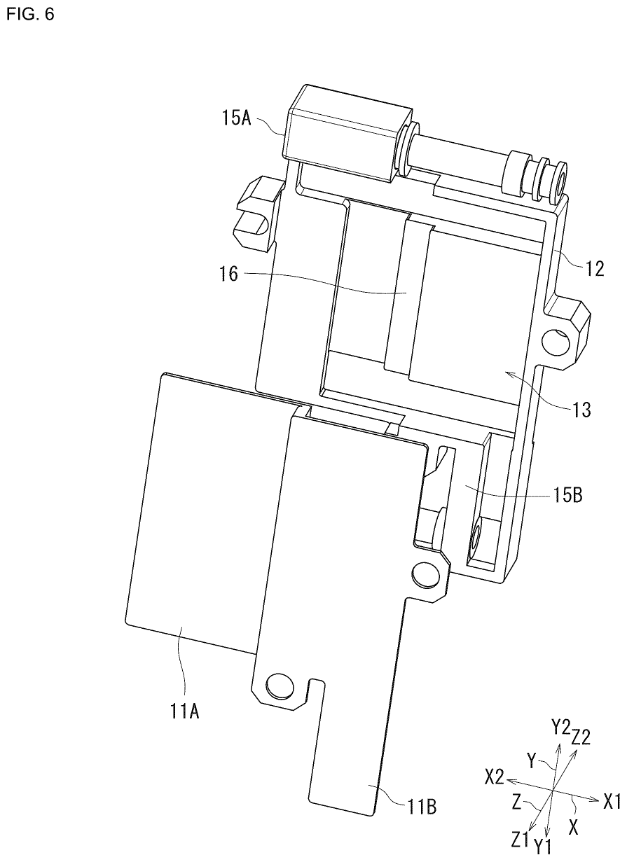

For example, the shape of the cover portion 12 is a substantially rectangular cuboid. The surface on the one side Z1 in the first direction (FIG. 6) of the cover portion 12 has an opening. The cover portion 12 covers the opposing portion 11. For example, the cover portion 12 is made of resin, metal, or the like.

When the opposing portion 11 is covered with the cover portion 12, the heat exchange chamber 13 is formed. In other words, the heat exchange chamber 13 is a region surrounded by the opposing portion 11, the surface on the other side Z2 in the first direction (FIG. 6) of the cover portion 12, and the four surfaces extending from four edges of the surface on the other side Z2 in the first direction of the cover portion 12 toward the one side Z1 in the first direction. For example, the opposing portion 11 and the cover portion 12 are fixed by brazing, welding, or the like. The refrigerant passes through the heat exchange chamber 13.

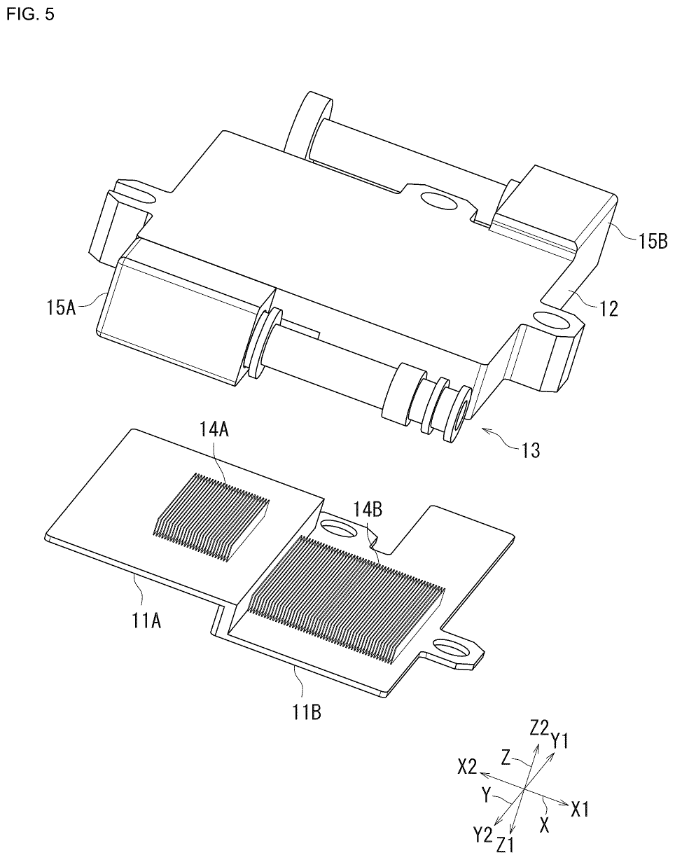

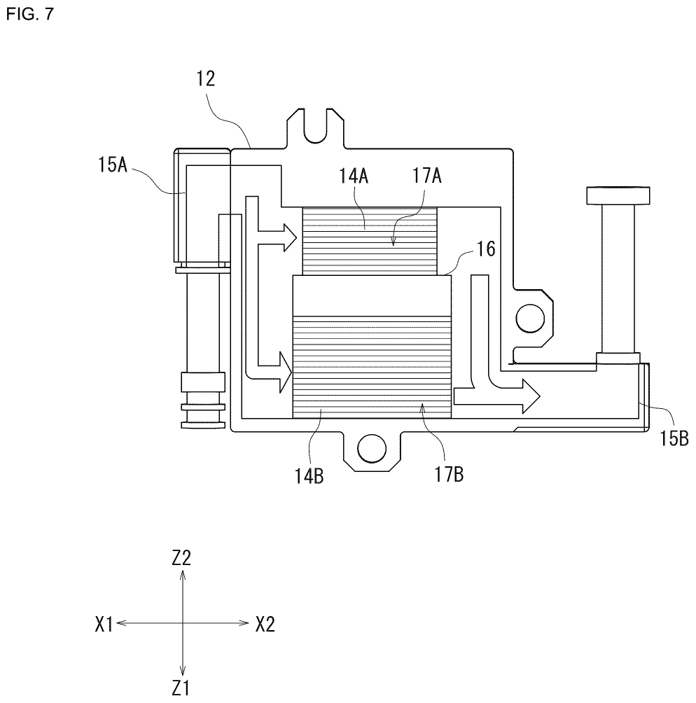

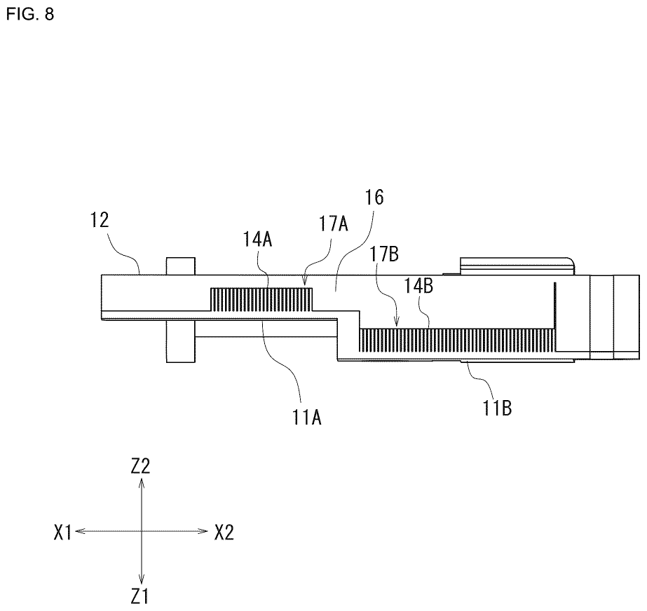

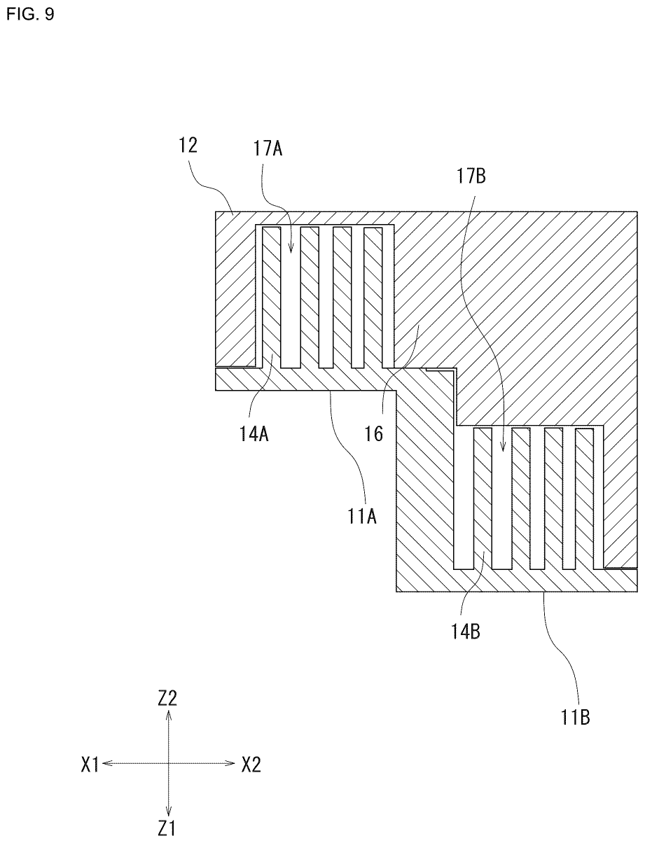

Next, the heat exchange chamber 13 will be described in detail with reference to FIGS. 5 to 9. FIG. 5 is a view showing the cold plate P1 in a state where the opposing portion 11 and the cover portion 12 are separated from each other. FIG. 6 is a view showing the opposing portion 11 and the cover portion 12 of FIG. from a different angle. FIG. 7 is a view showing the heat exchange chamber 13 seen through from the other side Z2 in the first direction. FIG. 8 is a sectional view of the heat exchange chamber 13 taken along the second direction X. FIG. 9 is a view schematically showing the sectional view shown in FIG. 8.

As shown in FIGS. 5 to 7, the cover portion 12 includes a first guide portion 15A and a second guide portion 15B. The first guide portion 15A guides the refrigerant from the outside to the inside of the heat exchange chamber 13. The second guide portion 15B guides the refrigerant from the inside to the outside of the heat exchange chamber 13. For example, the first guide portion 15A is connected to the manifold M1. The first guide portion 15A guides, into the heat exchange chamber 13, the refrigerant supplied by the manifold M1. For example, the second guide portion 15B is connected to a cold plate P2. The second guide portion 15B guides, to the cold plate P2, the refrigerant having passed through the heat exchange chamber 13. The connection destinations of the first guide portion 15A and the second guide portion 15B are not limited to the manifold M1 and the cold plate P2, respectively.

The heat exchange chamber 13 includes a first flow path 17A and a second flow path 17B. The first flow path 17A is provided on the other side Z2 in the first direction of the first cooling surface 11A. The second flow path 17B is provided on the other side Z2 in the first direction of the second cooling surface 11B. That is, the first flow path 17A and the second flow path 17B are arranged side by side in the second direction X. In the present example embodiment, the first flow path 17A and the second flow path 17B extend along the third direction Y orthogonal to the first direction Z and the second direction X. For example, in the first flow path 17A and the second flow path 17B, the one side Y1 in the third direction is a downstream side, and the other side Y2 in the third direction is an upstream side.

Specifically, the opposing portion 11 includes a first fin portion 14A and a second fin portion 14B. The first fin portion 14A is provided on the other side Z2 in the first direction of the first cooling surface 11A. The second fin portion 14B is provided on the other side Z2 in the first direction of the second cooling surface 11B. Each of the first fin portion 14A and the second fin portion 14B includes a plurality of fins. The fins of the first fin portion 14A protrude to the other side Z2 in the first direction of the first fin portion 14A and extend along the third direction Y. The fins of the second fin portion 14B protrude to the other side Z2 in the first direction of the second fin portion 14B and extend along the third direction Y.

As shown in FIGS. 8 and 9, the surface on the other side Z2 in the first direction of the first fin portion 14A comes into contact with the surface on the one side Z1 in the first direction of the cover portion 12. The surface on the other side Z2 in the first direction of the second fin portion 14B comes into contact with the surface on the one side Z1 in the first direction of the cover portion 12.

As shown in FIGS. 6 to 9, the cover portion 12 has a partition portion 16. The partition portion 16 is provided on the one side Z1 in the first direction of the cover portion 12. Specifically, the partition portion 16 protrudes toward the one side Z1 in the first direction of the cover portion 12 and extends along the third direction Y. That is, the partition portion 16 extends in the direction where the fins of the first fin portion 14A and the second fin portion 14B extend and along the first flow path 17A and the second flow path 17B. The partition portion 16 is positioned between the first fin portion 14A and the second fin portion 14B. In other words, the partition portion 16 partitions the first fin portion 14A and the second fin portion 14B, that is, the first flow path 17A and the second flow path 17B. This makes it easy to manufacture the partition portion 16 in the cold plate P1, and makes it possible to reduce the number of members in the cold plate P1. For example, the partition portion 16 is formed as one component formed of a single member with the cover portion 12.

As described above, in the heat exchange chamber 13, the first flow path 17A or the second flow path 17B is formed between the cover portion 12 and the fin, between the fin and the fin, and between the partition portion 16 and the fin. Part of the refrigerant guided inside the heat exchange chamber 13 by the first guide portion 15A passes through the first flow path 17A. Part of the refrigerant guided inside the heat exchange chamber 13 by the first guide portion 15A that has not passed through the first flow path 17A passes through the second flow path 17B. Therefore, the heat generating component H1 can be more efficiently cooled by branching and passing the refrigerant into the first flow path 17A and the second flow path 17B. Specifically, in FIG. 7, the movement of the refrigerant in the heat exchange chamber 13 is indicated by arrows. The second guide portion 15B guides, to the outside of the heat exchange chamber 13, the refrigerant after passing through the first flow path 17A and the refrigerant after passing through the second flow path 17B.

Specifically, in the first fin portion 14A and the second fin portion 14B, the heat of the heat generating component H1 is conducted to the refrigerant passing through the first flow path 17A or the second flow path 17B formed between the fins through the first cooling surface 11A and the second cooling surface 11B and the fins. In other words, the first fin portion 14A and the second fin portion 14B conduct the heat of the heat generating component H1 to the refrigerant. In this manner, the refrigerant passes through the first flow path 17A or the second flow path 17B formed between the fins, whereby the surface area where the refrigerant and the fins are in contact with each other becomes large, and the cooling performance of the cold plate P1 is improved.

In the present example embodiment, for example, the first flow path 17A and the second flow path 17B are connected in parallel to the first guide portion 15A and the second guide portion 15B. Therefore, the refrigerant having passed through the first guide portion 15A easily branches into the first flow path 17A and the second flow path 17B. As a result, the refrigerant having the same temperature passes through the first flow path 17A and the second flow path 17B, and therefore the cooling performances of the first cooling surface 11A and the second cooling surface 11B with respect to the heat generating component H1 can be made substantially the same. Specifically, the first guide portion 15A is positioned on the other side Y2 in the third direction. The second guide portion 15B is positioned on the one side Y1 in the third direction. That is, the first guide portion 15A is positioned on an upstream side with respect to the first flow path 17A and the second flow path 17B. The second guide portion 15B is positioned on a downstream side with respect to the first flow path 17A and the second flow path 17B.

For example, the first guide portion 15A is positioned on the other side X2 in the second direction. The second guide portion 15B is positioned on the one side X1 in the second direction. Therefore, the distance of a route from the first guide portion 15A to the second guide portion 15B through the first flow path 17A becomes substantially the same as the distance of a route from the first guide portion 15A to the second guide portion 15B through the second flow path 17B. As a result, a flow path capable of more efficiently cooling the heat generating component H1 is formed in the heat exchange chamber 13. That is, the first guide portion 15A and the second guide portion 15B are positioned on opposite sides to each other along the direction where the first flow path 17A and the second flow path 17B are arranged side by side.

The arrangement of the first guide portion 15A and the second guide portion 15B is not limited to the above. Specifically, the first guide portion 15A may be positioned on the downstream side with respect to the first flow path 17A and the second flow path 17B, and the second guide portion 15B may be positioned on the upstream side with respect to the first flow path 17A and the second flow path 17B. For example, the first guide portion 15A may be positioned on the one side X1 in the second direction, and the second guide portion 15B may be positioned on the other side X2 in the second direction. Furthermore, the first guide portion 15A and the second guide portion 15B may be positioned at substantially the same position along the second direction X.

The example embodiment of the present disclosure has been described above with reference to the drawings (FIGS. 1 to 9). However, the present disclosure is not limited to the above example embodiment, and can be implemented in various modes without departing from the gist of the present disclosure. Additionally, the plurality of constituent elements disclosed in the above example embodiment can be appropriately modified. For example, a certain constituent element of all constituent elements shown in a certain example embodiment may be added to a constituent element of another example embodiment, or some constituent elements of all constituent elements shown in a certain example embodiment may be removed from the example embodiment.

The drawings schematically show each constituent element mainly in order to facilitate understanding of the disclosure, and the thickness, length, number, interval, and the like of the shown constituent elements may be different from the actual ones for convenience of creation of the drawings. The configuration of each constituent element shown in the above example embodiment is an example and is not particularly limited, and it goes without saying that various modifications can be made without substantially departing from the effects of the present disclosure.

Example embodiments of the present disclosure are applicable to the field of cold plates.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cold plate comprising:
an opposing portion opposing a heat generating component on one side in a first direction;
a cover portion on another side of the opposing portion in the first direction; and
a heat exchange chamber including at least the opposing portion and the cover portion to conduct heat from the heat generating component to a refrigerant through the opposing portion; wherein
the opposing portion includes:
a first cooling surface on the one side in the first direction; and
a second cooling surface on the one side in the first direction; and
the second cooling surface is spaced away from the first cooling surface in the first direction.

2. The cold plate according to claim 1, wherein the first cooling surface and the second cooling surface are defined by a single structure.

3. The cold plate according to claim 1, wherein
the heat exchange chamber includes:
a first flow path through which the refrigerant passes; and
a second flow path through which the refrigerant passes;
the first flow path is on the other side of the first cooling surface in the first direction;
the second flow path is on the other side of the second cooling surface in the first direction; and
the first flow path and the second flow path are side by side in a second direction perpendicular or substantially perpendicular to the first direction.

4. The cold plate according to claim 3, wherein
the opposing portion includes:
a first fin portion to conduct heat from the heat generating component to the refrigerant; and
a second fin portion to conduct heat of the heat generating component to the refrigerant;
the first fin portion is on the other side of the first cooling surface in the first direction;
the second fin portion is on the other side of the first cooling surface in the first direction;
a surface on the other side of the first fin portion in the first direction comes into contact with a surface of the cover portion on the one side in the first direction; and
a surface on the other side of the second fin portion in the first direction comes into contact with a surface of the cover portion on the one side in the first direction.

5. The cold plate according to claim 3, wherein
the cover portion includes a partition portion that partitions the first flow path and the second flow path; and
the partition portion is provided on the one side of the cover portion in the first direction and extends along the first flow path and the second flow path.

6. The cold plate according to claim 3, wherein
the cover portion includes:
a first guide portion to guide the refrigerant from an outside to an inside of the heat exchange chamber; and
a second guide portion to guide the refrigerant from the inside to the outside of the heat exchange chamber;
the first guide portion is on one side in the second direction; and
the second guide portion is on another side in the second direction.

7. The cold plate according to claim 6, wherein the first flow path and the second flow path are connected in parallel to the first guide portion and the second guide portion.
